(19) United States
(12) Patent Application Publication
(10) Pub. No.: US 2026/0121637 A1
(43) Pub. Date: Apr. 30, 2026

(54) Self-Isolated Analog Circuit

(71) Applicants: Chongmei Zhang, Morgan Hill, CA (US); Ling Yu, Cupertino, CA (US); Maneesha Yellepeddi, Los Gatos, CA (US); Ping Xiao, East Palo Alto, CA (US)

(72) Inventors: Chongmei Zhang, Morgan Hill, CA (US); Ling Yu, Cupertino, CA (US); Maneesha Yellepeddi, Los Gatos, CA (US); Ping Xiao, East Palo Alto, CA (US)

(21) Appl. No.: 19/432,095

(22) Filed: Dec. 23, 2025

(51) Int. Cl. H03K 17/693; H03K 17/687

(52) U.S. Cl. CPC H03K 17/693; H03K 17/6872

(57) ABSTRACT

Integrated circuit devices and circuitry incorporating a self-isolated switch are provided. A self-isolated switch includes an N-type metal-oxide-semiconductor (NMOS) path that closes when the self-isolated switch receives an enable signal with a first voltage, and opens when the self-isolated switch receives the enable signal with a second voltage and when the self-isolated switch is powered down. The self-isolated switch also includes a P-type metal-oxide-semiconductor (PMOS) path that closes when the self-isolated switch receives the enable signal with the first voltage, and opens when the self-isolated switch receives the enable signal with the second voltage and when the self-isolated switch is powered down.

### BACKGROUND

This disclosure relates generally to self-isolated analog circuitry and, more specifically, to self-isolated analog multiplexers and switches for use in integrated circuit devices with multiple power domains.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuit devices, such as field-programmable gate arrays (FPGAs), increasingly incorporate multiple subsystems and disaggregated dies, each with independent analog and digital power domains. In many cases, the different domains may be powered up or down at different times to support advanced power management strategies. In these architectures, analog and power signals from various domains may be combined or routed for device characterization, debugging, or switching purposes. However, analog multiplexing and signal routing face significant challenges in maintaining proper isolation between domains, especially during power-up, power-down, or partial subsystem shutdown events. These challenges can result in increased design complexity, risk of signal contention, and additional circuitry or board-level constraints to ensure reliable operation across varying power states.

For instance, conventional complementary metal-oxide-semiconductor (CMOS) switches may be used to build an analog multiplexer for a shared analog test bus (ATB) or other analog switch designs. While a conventional CMOS switch may be able to pass an analog signal of a particular value between two rails when selected, a conventional CMOS switch may not isolate power domains without a complicated control scheme. For example, to use multiplexers formed using conventional CMOS switches, the integrated circuit device power-up/down may be specified to in a particular sequence to ensure the ATB multiplexer supply is powered up first and powered down last. The input signals from different power domains other than ATB multiplexer power domain may be pre-isolated. In some cases, rather than a CMOS switch, an N-type metal-oxide-semiconductor (NMOS) pass-gate-only switch may be used to avoid isolation concerns arising with P-type metal-oxide-semiconductor (PMOS), but with elevated NMOS gate control voltage level to ensure full analog signal passing. In addition, owing to the absence of thick gate devices in modern technologies, higher voltage signal transfer (e.g., higher compared to digital voltage rail) may use a low dropout regulator (LDO) to power the ATB multiplexers, which stay always on for proper isolation. Yet these schemes involve multiple integrated circuit package bumps and balls based on the power domains of the control signals and multiplexers used.

### BRIEF DESCRIPTION OF THE DRAWINGS

Various aspects of this disclosure may be better understood upon reading the following detailed description and upon reference to the drawings in which:

FIG. 1 is a block diagram of a disaggregated die system for a disaggregated integrated circuit device with self-isolated analog multiplexers and a shared analog bus;

FIG. 2 is a block diagram of the connections of self-isolated analog multiplexers across a shared analog bus in a disaggregated integrated circuit device;

FIG. 3 is a circuit diagram of a CMOS self-isolated analog switch;

FIG. 4 is a circuit diagram of a CMOS self-isolated analog switch built with four-terminal devices;

FIG. 5 is a diagram illustrating a CMOS self-isolated switch and corresponding equivalent circuit representations under ON and OFF conditions;

FIG. 6 is a circuit diagram illustrating a CMOS non-self-isolated analog switch circuit that may be used in combination with a CMOS self-isolated analog switch;

FIG. 7 is a circuit diagram of a self-isolated analog multiplexer;

FIG. 8 is a circuit diagram of a non-self-isolated multiplexer;

FIG. 9 is a circuit diagram of a larger self-isolated multiplexer formed using self-isolated multiplexers;

FIG. 10 is a circuit diagram of a larger self-isolated multiplexer formed using self-isolated multiplexers and non-self-isolated multiplexers; and

FIG. 11 is a system diagram illustrating the components of a data processing system incorporating a disaggregated die system.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

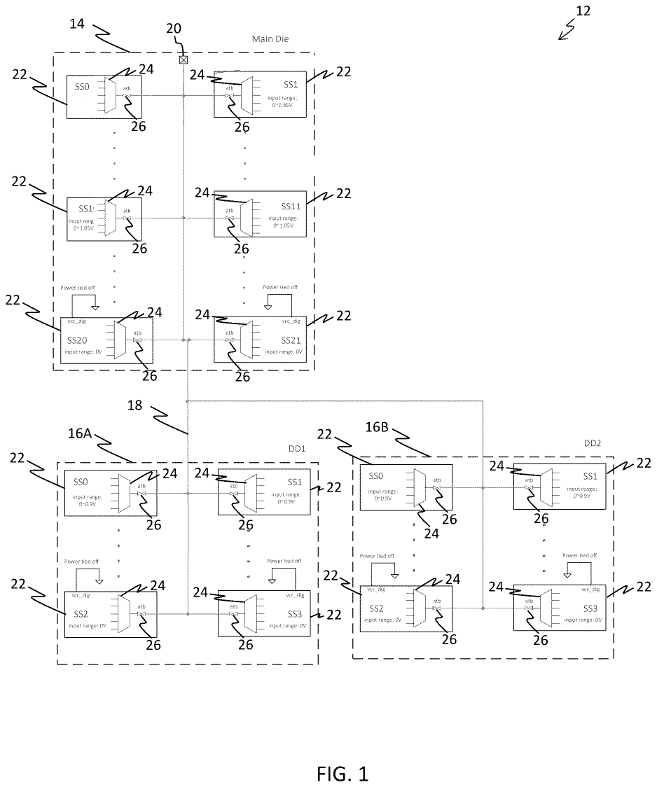

FIG. 1 is a block diagram of a disaggregated integrated circuit device 12 that may include several separate integrated circuit dies. Here, the integrated circuit device 12 includes a main die 14, a first disaggregated die (DD1) 16A and a second disaggregated die (DD2) 16B. In other examples, there may be more or fewer disaggregated dies 16 or multiple main dies 14. The main die 14, DD1 16A, and DD2 16B may include any suitable circuitry. For instance, the integrated circuit device 12 may include a programmable logic device (PLD), such as an FPGA (e.g., Agilex™, Stratix®, Arria®, MAX®, or Cyclone® devices by Altera® Corporation), or circuitry such as a processor (e.g., x86, reduced instruction set computer (RISC), advanced RISC machine (ARM), RISC-V). Note that, while this disclosure largely refers to the integrated circuit device 12 as being a programmable logic device, such as an FPGA, in some embodiments, the integrated circuit device 12 may also include a one-time programmable device or structured application specific integrated circuit (ASIC), such as an Intel® eASIC™ device by Intel® Corporation. In other examples, the integrated circuit device 12 may be any suitable integrated circuit that is manufactured to have a particular system design with circuitry to perform desired data processing operations. The integrated circuit device 12 may be a single monolithic integrated circuit with multiple power domains (not shown) or a multi-die system of integrated circuit dies (as depicted in FIG. 1). Thus, the integrated circuit device 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

Whether formed in separate dies or in a single monolithic die, the integrated circuit device 12 may include a shared analog bus 18, having an output pin 20, connected to multiple subsystems 22. In FIG. 1, the main die 14 includes subsystems 22 labeled SS0, SS1, . . . , SS10, SS11, . . . , SS20, SS21; the DD1 16A includes subsystems 22 labeled SS0, SS1, . . . , SS2, SS3; and the DD2 16B includes subsystems 22 labeled SS0, SS1, . . . , SS2, SS3. Different subsystems 22 may represent circuitry in different power domains. As such, the various subsystems 22 may operate at different power levels and may include analog circuitry operating with different signal levels. For example, some subsystems 22 may operate at 0.85V, some at 0.9V, some at 1.05V, and some may be powered off and thus may have a voltage of 0V. Moreover, in some embodiments, the various circuits of the different subsystems may also operate at different voltage levels. In some cases, such as for certain system design configurations programmed into the integrated circuit device 12 when the integrated circuit device 12 is an FPGA, unused subsystems 22 in the system design may have their power tied off and thus may remain in a permanently powered-down state while the integrated circuit device 12 is programmed in this way.

The shared analog bus 18 may carry any suitable analog signals. In one example, the shared analog bus 18 may operate as an analog test bus (ATB) for the integrated circuit device 12. The shared analog bus 18 is shown to be shared across all of the subsystems 22 across the entire integrated circuit device 12, but in other embodiments, there may be different shared analog buses 18 shared by certain subsets of the subsystems 22. The shared analog bus 18 may have any suitable width. For instance, the shared analog bus 18 may have a width of 1 bit, 2 bits, 3 bits, 4 bits, 6, bits, 8 bits, 10 bits, 12 bits, 16 bits, 20 bits, 32 bits, 64 bits, or the like. In any event, multiple subsystems 22 may share at least part of the shared analog bus 18. In some embodiments, because the shared analog bus 18 is shared by the various subsystems 22, the shared analog bus 18 may have no level shifters between the subsystems 22.

The subsystems 22 thus may be power-isolated on the shared analog bus 18 to prevent interfering with the operation of another subsystem 22. To enable a selected subsystem 22 or a selected circuit of a subsystem 22 to provide an analog signal over the shared analog bus 18, the connection point (e.g., access point) for each subsystem 22 to the shared analog bus 18 may include a multiplexer 24 and/or a self-isolated switch 26. In some cases, the multiplexers 24 may be formed from multiple self-isolated switches 26, but in other cases, the multiplexers 24 may be partially formed from conventional switches but isolated by a self-isolated switch 26. As used herein, the term “self-isolated switch” refers to a switch that, when not expressly enabled, defaults to an open position even while not powered up, which preserves power isolation even when the subsystem 22 to which it belongs is powered down.

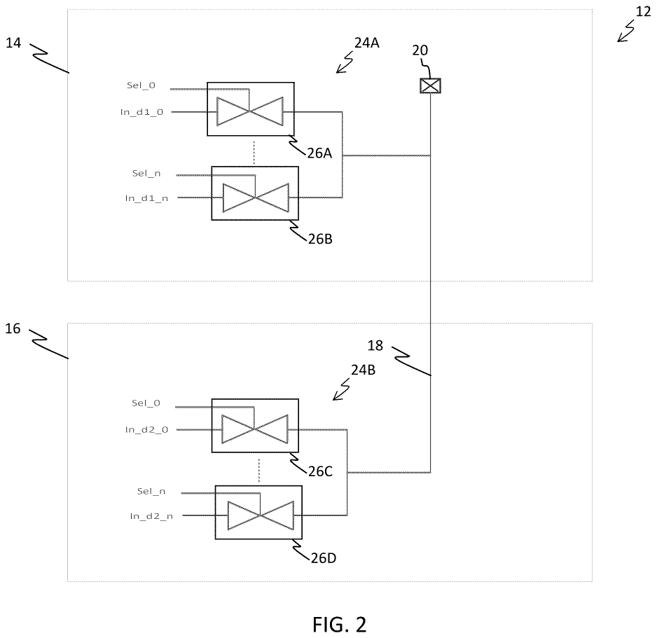

FIG. 2 is a block diagram of the integrated circuit device 12 that provides another perspective. The example of FIG. 2 shows the main die 14 and one disaggregated die 16. A multiplexer 24 on each die is formed from multiple self-isolated switches 26. For example, on the main die 14, a multiplexer 24A includes N+1 switches 26A . . . 26B. The switch 26A passes a data signal in_d1_0 based on a select signal Sel_0 and the switch 26B passes a data signal in_d1_n based on a select signal Sel_n. On the disaggregated die 16, a multiplexer 24B includes N+1 switches 26C . . . 26D. The switch 26C passes a data signal in_d2_0 based on a select signal Sel_0 and the switch 26D passes a data signal in_d2_n based on a select signal Sel_n. Based on which one of the switches 26 is active on the integrated circuit device 12, a particular analog signal in_d1_0, . . . , in_d1_n or in_d2_0, . . . , in_d2_n may be selected onto the shared analog bus 18 and read from the output pin 20.

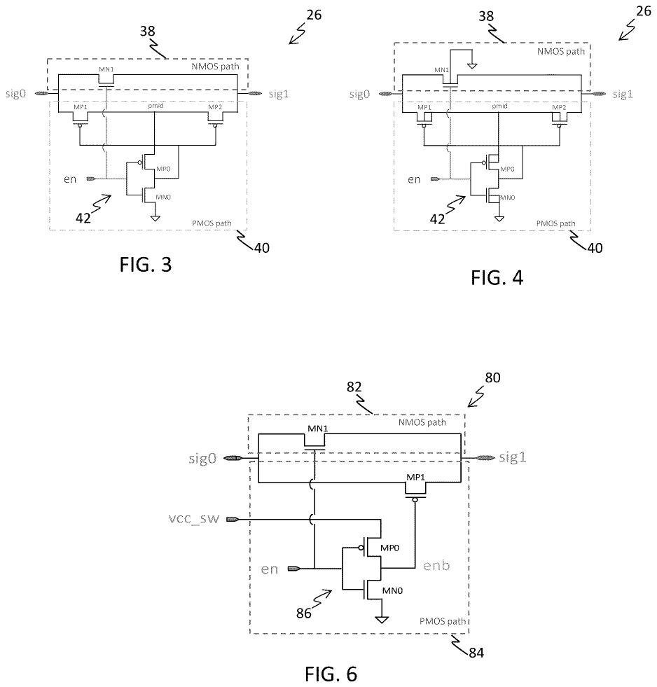

FIGS. 3 and 4 provide examples of the self-isolated switch 26. The circuits shown in FIGS. 3 and 4 are identical except that the circuit of FIG. 3 uses 3-terminal transistors (e.g., Intel 18A GAA devices) and FIG. 4 uses 4-terminal transistors. The self-isolated switch 26 is a CMOS circuit that includes an NMOS path 38 and a PMOS path 40. The NMOS path 38 includes an NMOS transistor MN1 with a gate connected to an enable signal (en). When the transistor MN1 is enabled by a logical high on the enable signal (en) (e.g., a switching VCC value vcc_sw), an input signal (sig0) at an input of the self-isolated switch 26 passes to an output as an output signal (sig1). When the transistor MN1 is not enabled by the enable signal (en), whether due to a logical low value on the enable signal (en) or due to the circuit being turned off and not supplied with power, the transistor MN1 is open and the input signal (sig0) is isolated from the output signal (sig1).

The PMOS path 40 includes PMOS transistors MP1 and MP2 connected in series between the input signal (sig0) and the output signal (sig1) (parallel to the NMOS path 38). The PMOS transistors MP1 and MP2 are enabled by an output of a modified CMOS inverter circuit 42 formed from a PMOS transistor MP0 and an NMOS transistor MN0. A gate of the NMOS transistor MN0 and a gate of the PMOS transistor MP0 receive the enable signal (en). A source of the NMOS transistor MN0 is connected to a low source voltage (e.g., ground, VSS). Rather than be connected to a high source voltage (e.g., VCC, VDD), a source of the PMOS transistor MP0 is connected to a middle voltage node (pmid) disposed between the PMOS transistors MP1 and MP2. An output of the modified CMOS inverter circuit 42 is connected to gates of the PMOS transistors MP1 and MP2.

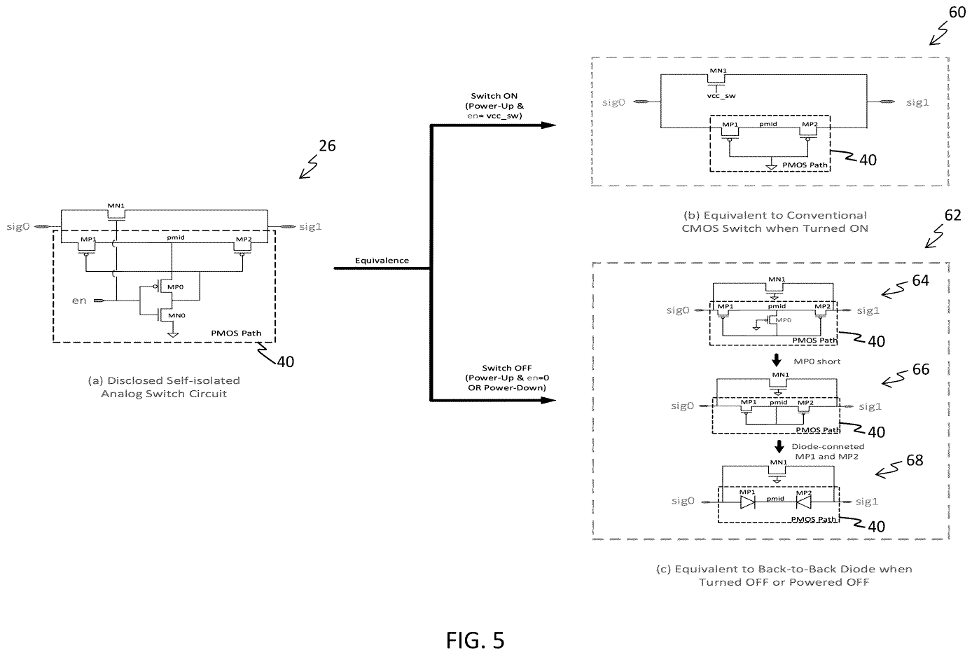

As shown in FIG. 5, this arrangement allows for the self-isolated analog switch 26 to behave like a normal analog switch while powered up, but to maintain power isolation while powered down. The lefthand side of the diagram of FIG. 5 illustrates the circuitry of the self-isolated analog switch 26 and the righthand side of the diagram of FIG. 5 illustrates equivalent circuits when the self-isolated analog switch 26 is powered on (equivalent circuit 60) and off (equivalent circuits 62).

The equivalent circuit 60 illustrates an equivalent circuit for the self-isolated analog switch 26 when the self-isolated analog switch 26 is powered on. The NMOS transistor MN1 receives an enable signal corresponding to a logical high value (vcc_sw), closing the NMOS path 38 between the input signal (sig0) and the output signal (sig1). When the modified CMOS inverter circuit 42 receives the enable signal (en) of a logical high value, the output of the modified CMOS inverter circuit 42 is a low value (e.g., ground, VSS). Thus, the gates of the PMOS transistors MP1 and MP2 of the PMOS path 40 are tied to ground, closing the PMOS path 40 between the input signal (sig0) and the output signal (sig1).

The equivalent circuits 62 illustrate equivalent circuits 64, 66, and 68 for the self-isolated analog switch 26 when the self-isolated analog switch 26 is powered off. In all the equivalent circuits 62, the NMOS path 38 between the input signal (sig0) and the output signal (sig1) is open because the NMOS transistor MN1 receives an enable signal corresponding to a logical low value. This may be true whether the enable signal (en) is purposely driven low or whether the self-isolated switch 26 is not connected to power. The PMOS path 40 of the self-isolated analog switch 26 also remains open, despite including PMOS transistors that are activated by low voltage values. This is because, as seen by the equivalent circuits 62, the PMOS transistor MP0 is connected to ground (equivalent circuit 64). This is equivalent to connecting the gates of the PMOS transistors MP1 and MP2 to the voltage node between them (pmid) (equivalent circuit 66), which is equivalent to treating the transistors MP1 and MP2 as two series-opposing back-to-back diodes (equivalent circuit 68). In this way, the PMOS path 40 is open between the input signal (sig0) and the output signal (sig1) even when powered down.

The self-isolated switch 26 may be seen as distinct from a non-self-isolated switch 80 as shown in FIG. 6. The non-self-isolated switch 80 of FIG. 6 may be used for power isolation in conjunction with self-isolated switches 26. The non-self-isolated switch 80 includes an NMOS path 82 with an NMOS transistor MN1 and a PMOS path 84 with a PMOS transistor MP1, but only the NMOS path 82 may be self-isolated when powered down. By contrast, the PMOS path 84 is activated by an output of a CMOS inverter 86 formed from a PMOS transistor MP0 and an NMOS transistor MN0 connected between ground and a logical high voltage (vcc_sw). Based on the value of an enable signal (en), the NMOS path 82 and the PMOS path 84 may simultaneously be closed or open during operation-except that, when powered down, the NMOS path 82 may be open while the PMOS path 84 may be closed. Thus, on its own, the non-self-isolated switch 80 may not provide power isolation when it is powered down.

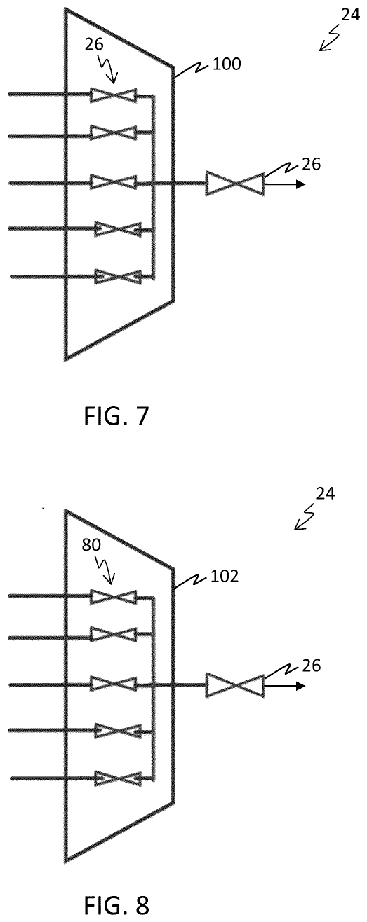

Non-self-isolated switches 80 may be used in circuits that provide power isolation, even when powered down, by operating in combination with one or more self-isolated switches 26. FIGS. 7 and 8, for example, provide example multiplexer circuits 100 and 102 that may form part of a multiplexer 24. In FIG. 7, a self-isolated multiplexer 100 may be formed from self-isolated switches 26 to achieve power isolation even when powered down. In FIG. 8, a non-self-isolated multiplexer 102 may be isolated from other circuits, even when powered down, using a self-isolated switch 26 at its output (but note that this circuit may not provide power isolation among different circuits connected to the inputs of the multiplexer 102 shown in FIG. 8).

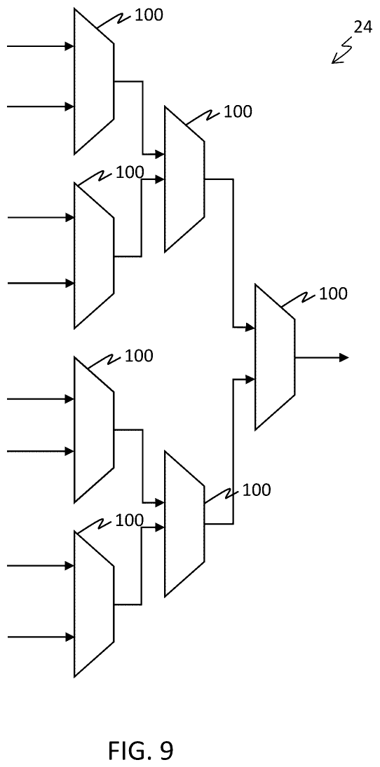

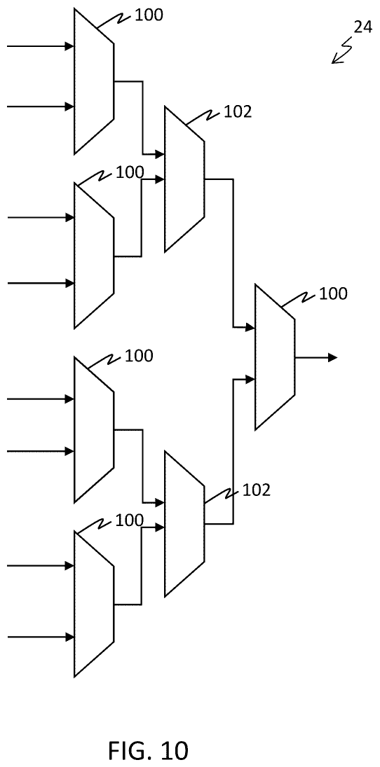

The various multiplexers 100 and 102 may be used to form larger self-isolated multiplexers 24, as shown in FIGS. 9 and 10. FIG. 9 illustrates one example of a self-isolated multiplexer formed from multiplexers 100. There may be more or fewer multiplexers 100 and the multiplexers 100 may have any suitable size (e.g., 2, 3, 4, 5, 6, 7, 8, or more inputs). FIG. 10 illustrates one example of a self-isolated multiplexer 24 that is fully self-isolated despite using some non-self-isolated multiplexers 102, since those are fully in series with self-isolated multiplexers 100. As with the example of FIG. 9, the example of FIG. 10 is provided by way of example, and there may be more or fewer multiplexers 100 and the multiplexers 100 may have any suitable size (e.g., 2, 3, 4, 5, 6, 7, 8, or more inputs).

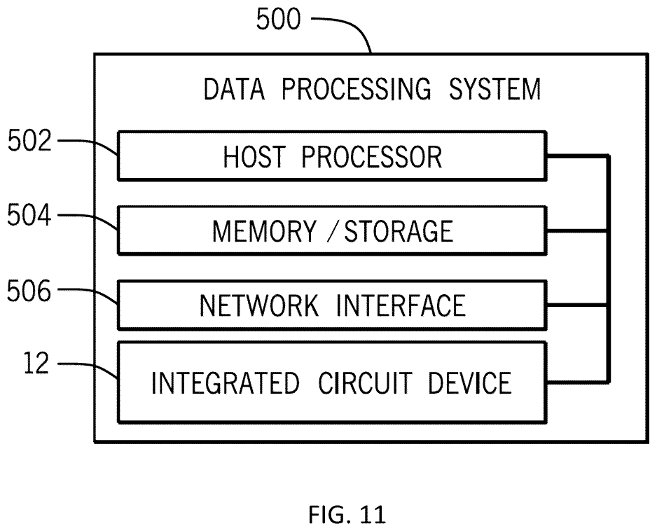

The integrated circuit device 12 discussed above may be a component included in a data processing system, such as a data processing system 500, shown in FIG. 11. The data processing system 500 may include the integrated circuit device 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A self-isolated switch comprising:
an N-type metal-oxide-semiconductor (NMOS) path configured to close when the self-isolated switch receives an enable signal with a first voltage, and configured to open when the self-isolated switch receives the enable signal with a second voltage and when the self-isolated switch is powered down; and
a P-type metal-oxide-semiconductor (PMOS) path configured to close when the self-isolated switch receives the enable signal with the first voltage, and configured to open when the self-isolated switch receives the enable signal with the second voltage and when the self-isolated switch is powered down.

EXAMPLE EMBODIMENT 2. The self-isolated switch of example embodiment 1, wherein the PMOS path is configured to operate as a pair of back-to-back diodes when the self-isolated switch is powered down.

EXAMPLE EMBODIMENT 3. The self-isolated switch of example embodiment 1, wherein the PMOS path comprises:
a first PMOS transistor, wherein a source of the first PMOS transistor is connected to an input of the self-isolated switch;
a second PMOS transistor, wherein a drain of the second PMOS transistor is connected to an output of the self-isolated switch and a source of the second PMOS transistor is connected to a drain of the first PMOS transistor;
an inverter circuit coupled between the second voltage and a middle voltage node, wherein the middle voltage node is located between the first PMOS transistor and the second PMOS transistor, wherein the inverter circuit is configured to receive the enable signal, and wherein:
when the enable signal has the first voltage, output the second voltage to a gate of the first PMOS transistor and a gate of the first PMOS transistor; and
when the enable signal has the second voltage, output a voltage corresponding to the middle voltage node to the gate of the first PMOS transistor and the gate of the second PMOS transistor.

EXAMPLE EMBODIMENT 4. The self-isolated switch of example embodiment 3, wherein the inverter circuit comprises a third PMOS transistor and a first NMOS transistor, wherein:
a source of the third PMOS transistor is connected to the middle voltage node;
a drain of the third PMOS transistor is connected to a drain of the first NMOS transistor, the gate of the first PMOS transistor, and the gate of the second PMOS transistor;
a source of the first NMOS transistor is connected to the ground voltage.

EXAMPLE EMBODIMENT 5. The self-isolated switch of example embodiment 1, wherein the first voltage comprises a positive voltage.

EXAMPLE EMBODIMENT 6. The self-isolated switch of example embodiment 1, wherein the second voltage comprises a ground voltage.

EXAMPLE EMBODIMENT 7. An integrated circuit device comprising:
a first subsystem configurable to operate in a first power domain;
   a second subsystem configurable to operate in a second power domain; and
   a bus shared between the first subsystem and the second subsystem, wherein the first subsystem and the second subsystem are power-isolated from one another via one or more self-isolated switches.

EXAMPLE EMBODIMENT 8. The integrated circuit device of example embodiment 7, wherein the integrated circuit device comprises a package comprising:
a first integrated circuit die that comprises the first subsystem;
a second integrated circuit die that comprises the second subsystem; and
the bus connects the first integrated circuit die and the second integrated circuit die.

EXAMPLE EMBODIMENT 9. The integrated circuit device of example embodiment 7, wherein:
the first subsystem comprises a first set of the one or more self-isolated switches at a first access point of the bus; and
the second subsystem comprises a second set of the one or more self-isolated switches at a second access point of the bus.

EXAMPLE EMBODIMENT 10. The integrated circuit device of example embodiment 7, wherein the first subsystem comprises a plurality of circuits configurable to operate at different power levels, wherein the circuits of the plurality of circuits are configurable to access the bus and are isolated from one another by at least one of the one or more self-isolated switches or one or more additional self-isolated switches.

EXAMPLE EMBODIMENT 11. The integrated circuit device of example embodiment 7, wherein the first subsystem and the second subsystem are configurable to be selectively powered down.

EXAMPLE EMBODIMENT 12. The integrated circuit device of example embodiment 7, wherein the first subsystem and the second subsystem are configurable to operate at different power levels.

EXAMPLE EMBODIMENT 13. The integrated circuit device of example embodiment 7, wherein the integrated circuit device comprises a field programmable gate array (FPGA) having a system design configuration in which the first subsystem is configured in a permanently powered-down state while the integrated circuit device has the system design configuration.

EXAMPLE EMBODIMENT 14. The integrated circuit device of example embodiment 7, wherein the bus comprises a shared analog bus.

EXAMPLE EMBODIMENT 15. The integrated circuit device of example embodiment 7, wherein the first subsystem or the second subsystem, or both, comprise a multiplexer that comprises at least one of the one or more self-isolated switches.

EXAMPLE EMBODIMENT 16. A multiplexer circuit comprising:
a first multiplexer comprising:
a first complementary metal-oxide-semiconductor (CMOS) switch of the first multiplexer configured to, when enabled, select a first input signal of the first multiplexer as an output signal of the first multiplexer; and
a second CMOS switch of the first multiplexer configured to, when enabled, select a second input signal of the first multiplexer as the output signal of the first multiplexer;
wherein the first CMOS switch of the first multiplexer or the second CMOS switch of the first multiplexer, or both, are self-isolated switches that default to open when the multiplexer circuit is powered down.

EXAMPLE EMBODIMENT 17. The multiplexer circuit of example embodiment 16, comprising:
a second multiplexer comprising:
a first CMOS switch of the second multiplexer configured to, when enabled, select a first input signal of the second multiplexer as an output signal of the second multiplexer; and
a second CMOS switch of the second multiplexer configured to, when enabled, select a second input signal of the second multiplexer as the output signal of the second multiplexer;
wherein the first CMOS switch of the second multiplexer or the second CMOS switch of the second multiplexer, or both, are non-self-isolated switches; and
wherein the output signal of the second multiplexer is the first input signal of the first multiplexer or the second input signal of the first multiplexer.

EXAMPLE EMBODIMENT 18. The multiplexer circuit of example embodiment 17, comprising:
a third multiplexer comprising:
a first CMOS switch of the third multiplexer configured to, when enabled, select a first input signal of the third multiplexer as an output signal of the third multiplexer; and
a second CMOS switch of the third multiplexer configured to, when enabled, select a second input signal of the third multiplexer as the output signal of the third multiplexer;
wherein the first CMOS switch of the third multiplexer or the second CMOS switch of the third multiplexer, or both, are self-isolated switches that default to open when the multiplexer circuit is powered down; and
wherein the output signal of the third multiplexer is the first input signal of the second multiplexer or the second input signal of the second multiplexer.

EXAMPLE EMBODIMENT 19. The multiplexer circuit of example embodiment 16, wherein the first CMOS switch of the first multiplexer is a self-isolated switch comprising a P-type metal-oxide-semiconductor (PMOS) path configured to operate as a pair of back-to-back diodes when the multiplexer circuit is powered down.

EXAMPLE EMBODIMENT 20. The multiplexer circuit of example embodiment 16, wherein the first CMOS switch of the first multiplexer is a self-isolated switch comprising a P-type metal-oxide-semiconductor (PMOS) path comprising:
a first PMOS transistor, wherein a source of the first PMOS transistor is connected to an input of the first CMOS switch of the first multiplexer;
a second PMOS transistor, wherein a drain of the second PMOS transistor is connected to an output of the first CMOS switch of the first multiplexer and a source of the second PMOS transistor is connected to a drain of the first PMOS transistor;
an inverter circuit coupled between the second voltage and a middle voltage node, wherein the middle voltage node is located between the first PMOS transistor and the second PMOS transistor, wherein the inverter circuit is configured to receive the enable signal, and wherein:
when an enable signal has the first voltage, output the second voltage to a gate of the first PMOS transistor and a gate of the first PMOS transistor; and
when the enable signal has the second voltage, output a voltage corresponding to the middle voltage node to the gate of the first PMOS transistor and the gate of the second PMOS transistor.

What is claimed is:

1. A self-isolated switch comprising:
an N-type metal-oxide-semiconductor (NMOS) path configured to close when the self-isolated switch receives an enable signal with a first voltage, and configured to open when the self-isolated switch receives the enable signal with a second voltage and when the self-isolated switch is powered down; and
a P-type metal-oxide-semiconductor (PMOS) path configured to close when the self-isolated switch receives the enable signal with the first voltage, and configured to open when the self-isolated switch receives the enable signal with the second voltage and when the self-isolated switch is powered down.

2. The self-isolated switch of claim 1, wherein the PMOS path is configured to operate as a pair of back-to-back diodes when the self-isolated switch is powered down.

3. The self-isolated switch of claim 1, wherein the PMOS path comprises:
a first PMOS transistor, wherein a source of the first PMOS transistor is connected to an input of the self-isolated switch;
a second PMOS transistor, wherein a drain of the second PMOS transistor is connected to an output of the self-isolated switch and a source of the second PMOS transistor is connected to a drain of the first PMOS transistor;
an inverter circuit coupled between the second voltage and a middle voltage node, wherein the middle voltage node is located between the first PMOS transistor and the second PMOS transistor, wherein the inverter circuit is configured to receive the enable signal, and wherein:
when the enable signal has the first voltage, output the second voltage to a gate of the first PMOS transistor and a gate of the first PMOS transistor; and
when the enable signal has the second voltage, output a voltage corresponding to the middle voltage node to the gate of the first PMOS transistor and the gate of the second PMOS transistor.

4. The self-isolated switch of claim 3, wherein the inverter circuit comprises a third PMOS transistor and a first NMOS transistor, wherein:
a source of the third PMOS transistor is connected to the middle voltage node;
a drain of the third PMOS transistor is connected to a drain of the first NMOS transistor, the gate of the first PMOS transistor, and the gate of the second PMOS transistor;
a source of the first NMOS transistor is connected to the ground voltage.

5. The self-isolated switch of claim 1, wherein the first voltage comprises a positive voltage.

6. The self-isolated switch of claim 1, wherein the second voltage comprises a ground voltage.

7. An integrated circuit device comprising:
a first subsystem configurable to operate in a first power domain;
a second subsystem configurable to operate in a second power domain; and
a bus shared between the first subsystem and the second subsystem, wherein the first subsystem and the second subsystem are power-isolated from one another via one or more self-isolated switches.

8. The integrated circuit device of claim 7, wherein the integrated circuit device comprises a package comprising:
a first integrated circuit die that comprises the first subsystem;
a second integrated circuit die that comprises the second subsystem; and
the bus connects the first integrated circuit die and the second integrated circuit die.

9. The integrated circuit device of claim 7, wherein:
the first subsystem comprises a first set of the one or more self-isolated switches at a first access point of the bus; and
the second subsystem comprises a second set of the one or more self-isolated switches at a second access point of the bus.

10. The integrated circuit device of claim 7, wherein the first subsystem comprises a plurality of circuits configurable to operate at different power levels, wherein the circuits of the plurality of circuits are configurable to access the bus and are isolated from one another by at least one of the one or more self-isolated switches or one or more additional self-isolated switches.

11. The integrated circuit device of claim 7, wherein the first subsystem and the second subsystem are configurable to be selectively powered down.

12. The integrated circuit device of claim 7, wherein the first subsystem and the second subsystem are configurable to operate at different power levels.

13. The integrated circuit device of claim 7, wherein the integrated circuit device comprises a field programmable gate array (FPGA) having a system design configuration in which the first subsystem is configured in a permanently powered-down state while the integrated circuit device has the system design configuration.

14. The integrated circuit device of claim 7, wherein the bus comprises a shared analog bus.

15. The integrated circuit device of claim 7, wherein the first subsystem or the second subsystem, or both, comprise a multiplexer that comprises at least one of the one or more self-isolated switches.

16. A multiplexer circuit comprising:
a first multiplexer comprising:
a first complementary metal-oxide-semiconductor (CMOS) switch of the first multiplexer configured to, when enabled, select a first input signal of the first multiplexer as an output signal of the first multiplexer; and
a second CMOS switch of the first multiplexer configured to, when enabled, select a second input signal of the first multiplexer as the output signal of the first multiplexer;
wherein the first CMOS switch of the first multiplexer or the second CMOS switch of the first multiplexer, or both, are self-isolated switches that default to open when the multiplexer circuit is powered down.

17. The multiplexer circuit of claim 16, comprising:
a second multiplexer comprising:
a first CMOS switch of the second multiplexer configured to, when enabled, select a first input signal of the second multiplexer as an output signal of the second multiplexer; and
a second CMOS switch of the second multiplexer configured to, when enabled, select a second input signal of the second multiplexer as the output signal of the second multiplexer;
wherein the first CMOS switch of the second multiplexer or the second CMOS switch of the second multiplexer, or both, are non-self-isolated switches; and
wherein the output signal of the second multiplexer is the first input signal of the first multiplexer or the second input signal of the first multiplexer.

18. The multiplexer circuit of claim 17, comprising:
a third multiplexer comprising:
a first CMOS switch of the third multiplexer configured to, when enabled, select a first input signal of the third multiplexer as an output signal of the third multiplexer; and
a second CMOS switch of the third multiplexer configured to, when enabled, select a second input signal of the third multiplexer as the output signal of the third multiplexer;
wherein the first CMOS switch of the third multiplexer or the second CMOS switch of the third multiplexer, or both, are self-isolated switches that default to open when the multiplexer circuit is powered down; and
wherein the output signal of the third multiplexer is the first input signal of the second multiplexer or the second input signal of the second multiplexer.

19. The multiplexer circuit of claim 16, wherein the first CMOS switch of the first multiplexer is a self-isolated switch comprising a P-type metal-oxide-semiconductor (PMOS) path configured to operate as a pair of back-to-back diodes when the multiplexer circuit is powered down.

20. The multiplexer circuit of claim 16, wherein the first CMOS switch of the first multiplexer is a self-isolated switch comprising a P-type metal-oxide-semiconductor (PMOS) path comprising:
a first PMOS transistor, wherein a source of the first PMOS transistor is connected to an input of the first CMOS switch of the first multiplexer;
a second PMOS transistor, wherein a drain of the second PMOS transistor is connected to an output of the first CMOS switch of the first multiplexer and a source of the second PMOS transistor is connected to a drain of the first PMOS transistor;
an inverter circuit coupled between the second voltage and a middle voltage node, wherein the middle voltage node is located between the first PMOS transistor and the second PMOS transistor, wherein the inverter circuit is configured to receive the enable signal, and wherein:
when an enable signal has the first voltage, output the second voltage to a gate of the first PMOS transistor and a gate of the first PMOS transistor, and
when the enable signal has the second voltage, output a voltage corresponding to the middle voltage node to the gate of the first PMOS transistor and the gate of the second PMOS transistor.
